(19) United States
(12) Patent Application Publication
(10) Pub. No.: US 2025/0269532 A1
(43) Pub. Date: Aug. 28, 2025

(54) SUBSTRATE TRANSPORT SYSTEM

(71) Applicant: SUMCO Corporation, Tokyo (JP)

(72) Inventors: Takayoshi TAKUSHIMA, Tokyo (JP); Kento MARUYAMA, Tokyo (JP)

(73) Assignee: SUMCO Corporation, Tokyo (JP)

(21) Appl. No.: 19/008,977

(22) Filed: Jan. 3, 2025

(30) Foreign Application Priority Data
Feb. 22, 2024 (JP) 2024-025640

(51) Int. Cl. B25J 9/16; B25J 11/00

(52) U.S. Cl. CPC B25J 9/1674; B25J 9/1697; B25J 11/0095

(57) ABSTRACT

The system has: a transport section that transports a substrate so that the substrate reaches A position, B position, C position, the B position, and the A position in this order, a A sensor that detects presence of the substrate that has reached the A position, a B sensor that detects presence of the substrate that has reached the B position, a timekeeping section that measures elapsed time when the A sensor and the B sensor detect the presence of the substrate in this order, and an abnormality detection unit that photographs the substrate that has reached the C position, and detects presence or absence of an abnormality in transport of the substrate based on the elapsed time measured by the timekeeping section and an image obtained by the photographing.

### TECHNICAL FIELD

This disclosure relates to a substrate transport system.

### BACKGROUND

A substrate transport system for transporting substrates has been known (see, for example, Patent Document 1).

### CITATION LIST

### Patent Literature

PTL 1: JP 2013-110200 A1

### SUMMARY

The object of this disclosure is to provide a substrate transport system that can reduce the burden of data processing when detecting, by photographing, the presence or absence of an abnormality in transport of a substrate.

One aspect of the present disclosure is as follows.
[1] A substrate transport system having:
a transport section that transports a substrate so that the substrate reaches A position, B position, C position, the B position, and the A position in this order,
a A sensor that detects presence of the substrate that has reached the A position,
a B sensor that detects presence of the substrate that has reached the B position,
a timekeeping section that measures elapsed time when the A sensor and the B sensor detect the presence of the substrate in this order, and
an abnormality detection unit that photographs the substrate that has reached the C position, and detects presence or absence of an abnormality in transport of the substrate based on the elapsed time measured by the timekeeping section and an image obtained by the photographing.
[2] The substrate transport system as described in [1], wherein the abnormality detection unit performs the photographing at a timing determined based on the elapsed time measured by the timekeeping section.
[3] The substrate transport system as described in [1] or [2], having a notification section that makes a notification when the abnormality detection unit detects the presence of an abnormality in transport of the substrate.
[4] The substrate transport system as described in [3], having:
a second transport section that transports a second substrate so that the second substrate reaches second A position, second B position, second C position, the second B position, and the second A position in this order,
a second A sensor that detects presence of the second substrate that has reached the second A position, and
a second B sensor that detects presence of the second substrate that has reached the second B position, wherein
the timekeeping section measures second elapsed time when the second A sensor and the second B sensor detect the presence of the second substrate in this order,
the abnormality detection unit performs second photographing of the second substrate that has reached the second C position, and detects presence or absence of an abnormality in transport of the second substrate based on the second elapsed time measured by the timekeeping section and an image obtained by the second photographing, and
the notification section makes a notification when the abnormality detection unit detects the presence of an abnormality in transport of the second substrate.

According to the present disclosure, it is possible to provide a substrate transport system that can reduce the burden of data processing when detecting, by photographing, the presence or absence of an abnormality in transport of a substrate.

### BRIEF DESCRIPTION OF THE DRAWINGS

In the accompanying drawings:

FIG. 1 is a top view of a first transport processing unit of the substrate transport system in accordance with one embodiment of the present disclosure;

FIG. 2 is an A-A cross-sectional view of FIG. 1, illustrating the state when the first substrate being transported by the first transport section has reached first A position;

FIG. 3 is a cross-sectional view illustrating the state when the first substrate has reached first B position after being transported from the state illustrated in FIG. 2;

FIG. 4 is a cross-sectional view illustrating the state when the first substrate has reached first C position after being transported from the state illustrated in FIG. 3; and

FIG. 5 is a schematic diagram illustrating the overall substrate transport system illustrated in FIG. 1.

### DETAILED DESCRIPTION

Hereinafter, an embodiment of the present disclosure will be described with reference to the drawings.

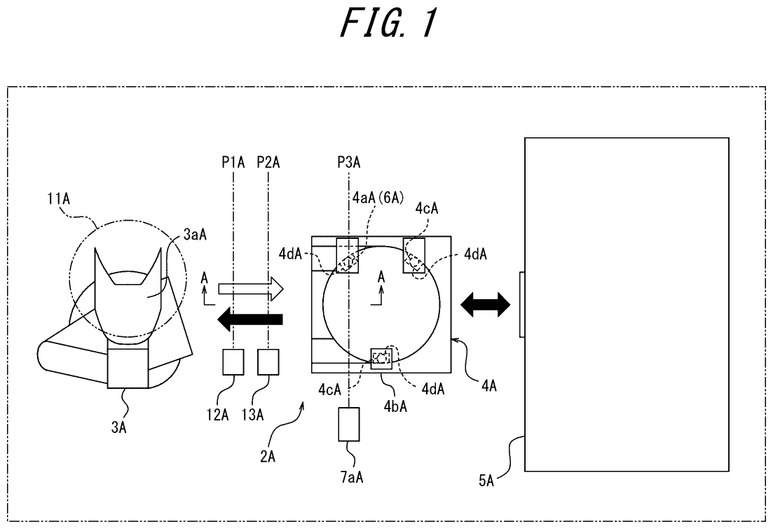

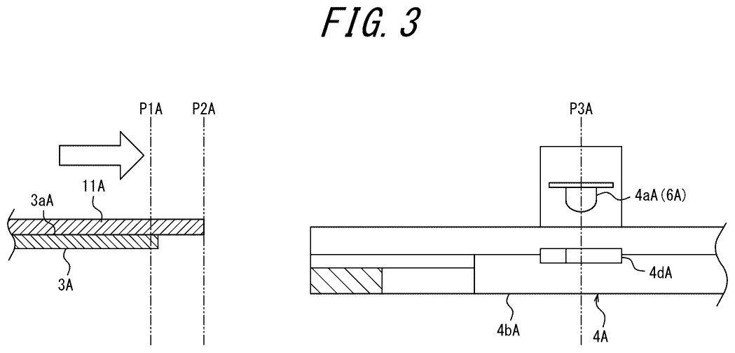

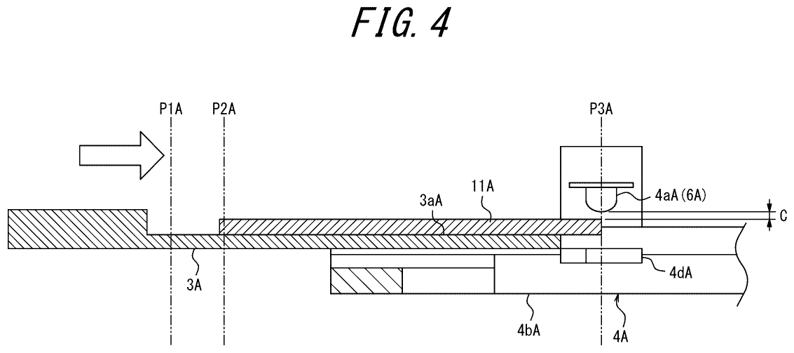

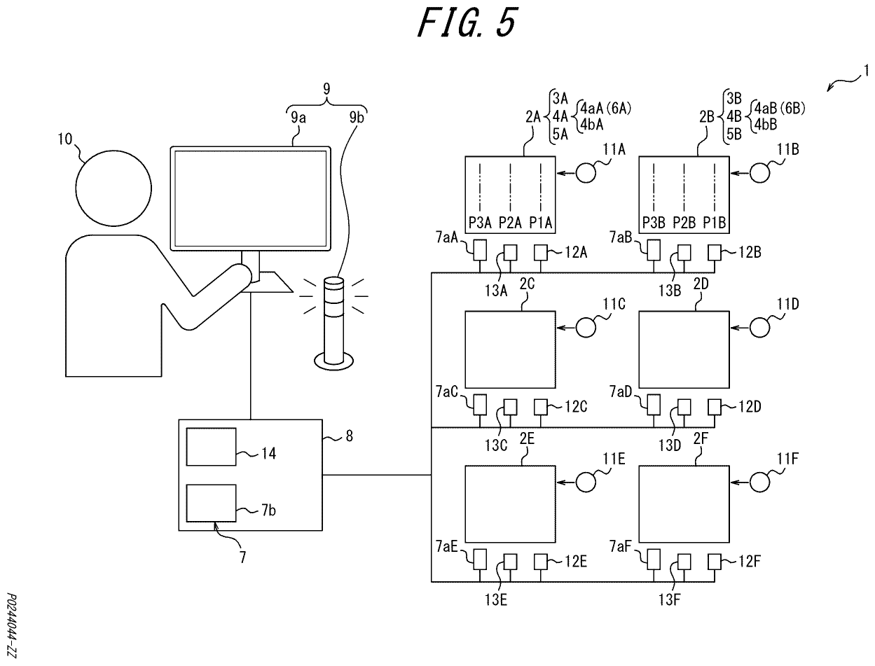

As illustrated in FIGS. 1 to 5, in one embodiment of the present disclosure, the substrate transport system 1 (see FIG. 5) has:

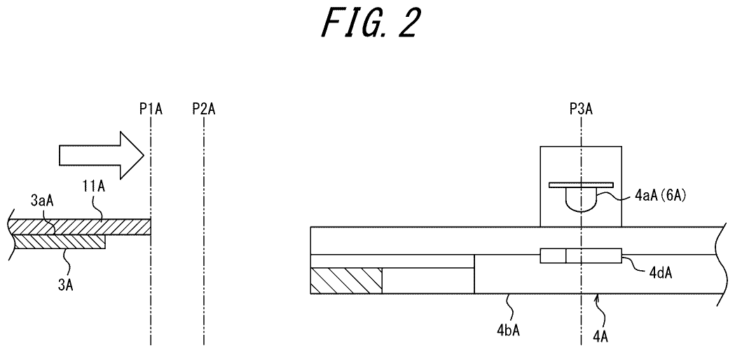

a (first) transport section 3A (see FIG. 1) that transports a substrate 11A so that the substrate 11A reaches (first) A position PIA, (first) B position P2A, (first) C position P3A, the B position P2A, and the A position PIA in this order (see FIGS. 2 to 4), a (first) A sensor 12A (see FIG. 1) that detects presence of the substrate 11A that has reached the A position PIA, a (first) B sensor 13A (see FIG. 1) that detects presence of the substrate 11A that has reached the B position P2A, a timekeeping section 14 (see FIG. 5) that measures (first) elapsed time when the A sensor 12A and the B sensor 13A detect the presence of the substrate 11A in this order, and an abnormality detection unit 7 (see FIG. 5) that photographs the substrate 11A that has reached the C position P3A, and detects presence or absence of an abnormality in transport of the substrate 11A at the C position P3A based on the elapsed time measured by the timekeeping section 14 and an image obtained by the photographing.

As illustrated in FIG. 5, in this embodiment, the substrate transport system 1 has a (first) transport processing unit 2A which has the (first) transport section 3A, a (first) transport pallet 4A, and a (first) processing section 5A; and a second transport processing unit 2B which has a second transport section 3B, a second transport pallet 4B, and a second processing section 5B. The (first) transport pallet 4A has a (first) gripper 4aA as a (first) system component 6A and a (first) pallet 4bA. The second transport pallet 4B has a second gripper 4aB as a second system component 6B and a second pallet 4bB. In addition, the substrate transport system 1 has a third transport processing unit 2C, a fourth transport processing unit 2D, a fifth transport processing unit 2E, and a sixth transport processing unit 2F. It will be noted that the number of the transport processing units in the substrate transport system 1 can be set as appropriate. The (first) transport processing unit 2A transports and processes the (first) substrate 11A, the second transport processing unit 2B transports and processes the second substrate 11B, the third transport processing unit 2C transports and processes the third substrate 11C, the fourth transport and processing unit 2D transports and processes the fourth substrate 11D, the fifth transport processing unit 2E transports and processes the fifth substrate 11E, and the sixth transport processing unit 2F transports and processes the sixth substrate 11F.

The substrate transport system 1 has the abnormality detection unit 7 (see FIG. 5) which has a (first) imaging section 7aA for the (first) transport processing unit 2A, a second imaging section 7aB for the second transport processing unit 2B, and a judgment section 7b; and a notification section 9 (see FIG. 5). The judgment section 7b is capable of communicating with the notification section 9, the (first) imaging section 7aA, and the second imaging section 7aB. In addition, the abnormality detection unit 7 has a third imaging section 7aC for the third transport processing unit 2C, a fourth imaging section 7aD for the fourth transport processing unit 2D, a fifth imaging section 7aE for the fifth transport processing unit 2E, and a sixth imaging section 7aF for the sixth transport processing unit 2F.

The substrate transport system 1 has the (first) A sensor 12A and the (first) B sensor 13A for the (first) transport processing unit 2A, and the (second) A sensor 12B and the (second) B sensor 13B for the (second) transport processing unit 2B. The timekeeping section 14 is capable of communicating with the (first) A sensor 12A, the (first) B sensor 13A, the second A sensor 12B, the second B sensor 13B, and the abnormality detection unit 7. In addition, the substrate transport system 1 has a third A sensor 12C and a third B sensor 13C for the third transport processing unit 2C, a fourth A sensor 12D and a fourth B sensor 13D for the fourth transport processing unit 2D, a fifth A sensor 12E and a fifth B sensor 13E for the fifth transport processing unit 2E, and a sixth A sensor 12F and a sixth B sensor 13F for the sixth transport processing unit 2F.

In this embodiment, when the substrate 11A (such as a silicon wafer) is transported by the transport section 3A to reach the A position P1A, the B position P2A, and the C position P3A in this order, the abnormality detection unit 7 detects the presence or absence of an abnormality in the transport of the substrate 11A at the C position by processing the image obtained by photographing the substrate 11A that has reached the C position P3A. In this case, from the perspective of minimizing the burden on the abnormality detection unit 7 through image processing, etc., the detection of an abnormality is only necessary when the substrate 11A reaches the C position P3A.

According to this embodiment, the timing at which the substrate 11A reaches the C position P3A can be identified using the A sensor 12A, the B sensor 13A and the timekeeping section 14. In other words, if the time required for the transport section 3A to transport the substrate 11A from the B position P2A to the C position P3A is known, the elapsed time can be measured by the timekeeping section 14 when the A sensor 12A and the B sensor 13A detect the presence of the substrate 11A in this order, and it can be judged that the substrate 11A has reached the C position P3A when the elapsed time reaches the above-mentioned time required. Also, when the sensors A12A and B13A detect the presence of the substrate 11A in the reverse order, it is possible for the abnormality detection unit 7 not to detect the presence or absence of an abnormality (preferably, without photographing using the abnormality detection unit 7, and even more preferably, without photographing using the abnormality detection unit 7 and measuring the elapsed time using the timekeeping section 14). Therefore, the abnormality detection unit 7 can detect the presence or absence of an abnormality in the transport of the substrate 11A only when the substrate 11A has reached the C position P3A, based on the elapsed time measured by the timekeeping section 14 and the image obtained by the photographing. In addition, the A sensor 12A and the B sensor 13A can be configured with simple sensors such as laser sensors, for example, and the burden of data processing can be reduced. Therefore, it is possible to realize a substrate transport system 1 that can reduce the burden of data processing when detecting, by photographing, the presence or absence of abnormalities in the transport of the substrate 11A.

The abnormality detection unit 7 performs the photographing using the imaging section 7aA at a timing determined based on the elapsed time measured by the timekeeping section 14. According to the above configuration, by specifying the timing at which the substrate 11A reaches the C position P3A using the A sensors 12A, the B sensor 13A, and the timekeeping section 14, and then performing the photographing using the abnormality detection unit (imaging section 7A), it is possible to avoid performing photographing at unnecessary times when detecting the presence or absence of an abnormality in the transport of the substrate 11A. This allows to reduce the burden of photographing on the abnormality detection unit 7, and further reduce the burden on data processing thereof. The image photographed by the abnormality detection unit 7 can be a still image in this embodiment, but it is not limited to this and can also be a video image. If the image captured by the abnormality detection unit 7 is a video image, the abnormality detection unit 7 may be configured to start and stop photographing at timings determined based on the elapsed time measured by the timekeeping section 14. The imaging section 7aA is configured with a camera, etc., such as a CCD (Charge Coupled Device) image sensor.

The abnormality detection unit 7 detects the presence or absence of an abnormality in the transport of the substrate 11A, using the judgment section 7b, based on the image obtained by the imaging section 7aA. In this embodiment, as the presence or absence of an abnormality in the transport of the substrate 11A, the presence or absence of an abnormality in the clearance C between the main surface of the substrate 11A (in this embodiment, the top surface of the disk-shaped substrate 11A) and the system component 6A is detected. The judgment section 7b and the timekeeping section 14 are configured with a processing device 8 (computer, etc.) that can process the images obtained by the imaging section 7aA.

The substrate transport system 1 has the gripper 4aA as a system component 6A and the pallet 4bA, and the gripper 4aA holds the substrate 11A between a receiving part 4dA of the pallet 4bA and the gripper 4aA itself by moving forward with respect to the pallet 4bA, and releases the substrate 11A by moving backward with respect to the pallet 4bA. In addition to the gripper 4aA and the pallet 4bA, the transport pallet 4A has a plurality of other grippers 4cA. The number of other grippers 4cA provided on the transport pallet 4A is two in this embodiment, but this is not limited to this number. The transport pallet 4A may be configured without the other grippers 4cA. The gripper 4aA and the other grippers 4cA can be formed using fluororesin such as polytetrafluoroethylene as a material. The receiving part 4dA for the gripper 4aA and the other receiving parts 4dA for the other grippers 4cA can be formed using materials such as engineering plastics such as PEEK (poly ether ether ketone).

Transport section 3A performs the first transport (see the white arrow pointing to the right in FIG. 1) that transports the substrate 11A toward the system component 6A in the forward direction so that the substrate 11A reaches the A position P1A, the B position P2A, and the C position P3A in this order; and the second transport (see the thick arrow pointing to the left in FIG. 1) that transports the substrate 11A away from the system component 6A in the backward direction so that the substrate 11A reaches the C position P3A, the B position P2A, and the A position P1A in this order.

The transport section 3A is configured with a robot arm with a placement section 3aA on which the substrate 11A is placed. The substrate 11A which has been placed on the placement section 3A is placed on the pallet 4bA of the transport pallet 4A by the first transport performed by the transport section 3A, and is held between the gripper 4aA and the receiving part 4DA of the pallet 4bA. The substrate 11A is transported into the processing section 5A by the transport pallet 4A in this state, and after the prescribed processing, the substrate 11A is returned to its original position by the transport pallet 4A (see the double-headed thick arrow in FIG. 1). Furthermore, the substrate 11A is released by the retraction of the gripper 4A, and is transported from the transport pallet 4A by the second transport performed by the transport section 3A.

As illustrated in FIG. 5, the substrate transport system 1 has a notification section 9 that makes a notification when the abnormality detection unit 7 detects the presence of an abnormality in the transport of the substrate 11A. According to the above configuration, by notifying the system administrator 10 of the abnormality through a notification, it is possible to call their attention or prompt them to take measures such as inspecting the substrate transport system 1 or stopping its operation. The notification section 9 can be configured with a monitor 9a that provides notification by displaying information on the screen, a warning light 9b that provides notification by light, or a buzzer (not illustrated) that provides notification by sound, but this is not limited to these.

As illustrated in FIG. 5, the substrate transport system 1 has: a second transport section 3B that transports a second substrate 11B so that the second substrate 11B reaches second A position P1B, second B position P2B, second C position P3B, the second B position P2B, and the second A position P1B in this order, a second A sensor 12B that detects presence of the second substrate 11B that has reached the second A position P1B, and a second B sensor 13B that detects presence of the second substrate 11B that has reached the second B position P2B, wherein the timekeeping section 14 measures second elapsed time when the second A sensor 12B and the second B sensor 13B detect the presence of the second substrate 11B in this order, the abnormality detection unit 7 performs second photographing of the second substrate 11B that has reached the second C position P3B, and detects presence or absence of an abnormality in transport of the second substrate 11B based on the second elapsed time measured by the timekeeping section 14 and an image obtained by the second photographing, and the notification section 9 makes a notification when the abnormality detection unit 7 detects the presence of an abnormality in transport of the second substrate 11B at the second C position P3B. According to the above configuration, it is possible to use the common judgment section 7b, timekeeping section 14 and notification section 9 to detect the presence or absence of an abnormality in the transport of the (first) substrate 11A at the (first) C position P3A and to notify of this, as well as to detect the presence or absence of an abnormality in the transport of the (second) substrate 11B at the (second) C position P3B and to notify of this, therefore, efficient operation of the entire system can be achieved. It will be noted that the substrate transport system 1 is not limited to the above configuration that uses a common judgment section 7b and timekeeping section 14. For example, the system 1 may be configured to have a first judgment section and a first timekeeping section (not illustrated) for detecting the presence or absence of an abnormality in the transport of the first substrate 11A at the (first) C position P3A, and a second judgment section and a second timekeeping section (not illustrated) for detecting the presence or absence of an abnormality in the transport of the second substrate 11B at the (second) C position P3B.

The abnormality detection unit 7 performs the photographing using the second imaging section 7aB at a timing determined based on the second elapsed time measured by the timekeeping section 14. The abnormality detection unit 7 detects the presence or absence of an abnormality in the transport of the second substrate 11B, using the judgment section 7b, based on the image obtained by the second imaging section 7aB. As the presence or absence of an abnormality in the transport of the second substrate 11B, the presence or absence of an abnormality in the clearance C between the main surface of the second substrate 11B and the second system component 6B is detected. Although the embodiment of the present disclosure has been

described above, the present disclosure is not limited to the above-described embodiment, and the above-described embodiment can be modified in various ways without departing from the gist of the present disclosure.

1. A substrate transport system having:
a transport section that transports a substrate so that the substrate reaches A position, B position, C position, the B position, and the A position in this order,
a A sensor that detects presence of the substrate that has reached the A position,
a B sensor that detects presence of the substrate that has reached the B position,
a timekeeping section that measures elapsed time when the A sensor and the B sensor detect the presence of the substrate in this order, and
an abnormality detection unit that photographs the substrate that has reached the C position, and detects presence or absence of an abnormality in transport of the substrate based on the elapsed time measured by the timekeeping section and an image obtained by the photographing.

2. The substrate transport system as described in claim 1, wherein the abnormality detection unit performs the photographing at a timing determined based on the elapsed time measured by the timekeeping section.

3. The substrate transport system as described in claim 1, having a notification section that makes a notification when the abnormality detection unit detects the presence of an abnormality in transport of the substrate.

4. The substrate transport system as described in claim 3, having:
a second transport section that transports a second substrate so that the second substrate reaches second A position, second B position, second C position, the second B position, and the second A position in this order,
a second A sensor that detects presence of the second substrate that has reached the second A position, and
a second B sensor that detects presence of the second substrate that has reached the second B position, wherein
the timekeeping section measures second elapsed time when the second A sensor and the second B sensor detect the presence of the second substrate in this order,
the abnormality detection unit performs second photographing of the second substrate that has reached the second C position, and detects presence or absence of an abnormality in transport of the second substrate based on the second elapsed time measured by the timekeeping section and an image obtained by the second photographing, and
the notification section makes a notification when the abnormality detection unit detects the presence of an abnormality in transport of the second substrate.
